(19) United States
(12) Patent Application Publication
(10) Pub. No.: US 2026/0095140 A1
(43) Pub. Date: Apr. 2, 2026

(54) RESONATOR WITH SPUR MITIGATION DEVICE

(71) Applicant: TEXAS INSTRUMENTS INCORPORATED, Dallas, TX (US)

(72) Inventors: Bichoy BAHR, Allen, TX (US); Kashyap MOHAN, McKinney, TX (US); Yujing ZHANG, Richardson, TX (US); Baher S. HAROUN, Allen, TX (US); Michael T. WYANT, Dallas, TX (US)

(21) Appl. No.: 18/901,600

(22) Filed: Sep. 30, 2024

(51) Int. Cl. H03H 9/02; H03H 3/02; H03H 9/17

(52) U.S. Cl. CPC H03H 9/02086; H03H 3/02; H03H 9/175; H03H 2003/025

(57) ABSTRACT

An apparatus includes a semiconductor substrate, a bulk acoustic wave (BAW) resonator, and a coating or protrusion structures. The BAW resonator is on a first side of the semiconductor substrate. The coating and/or the protrusion structures are on a second side of the semiconductor substrate. The coating has a lower Young's modulus than the semiconductor substrate. The protrusion structures have uniform dimensions.

### BACKGROUND

A resonator is a device or system that naturally oscillates at a frequency called a resonant frequency. Resonators can be, for example, crystal resonators (also known as quartz resonators), inductance-capacitance (LC) resonators, or microelectromechanical system (MEMS) resonators. Resonators are generally passive devices that are combined with active circuitry to create an oscillator. The oscillator produces a periodic signal at the resonant frequency. A crystal oscillator, for example, is an electronic circuit that uses the mechanical resonance of a vibrating crystal to create an electrical signal with a very precise frequency. Crystal oscillators may be used to generate frequencies to keep track of time or to generate a clock signal for digital integrated circuits. MEMS resonators may be used in place of crystal resonators to keep track of time and to generate a stable clock signal for analog and digital integrated circuits.

### SUMMARY

In one example, an apparatus includes a semiconductor substrate, a bulk acoustic wave (BAW) resonator, and a coating. The BAW resonator is on a first side of the semiconductor substrate. The coating is on a second side of the semiconductor substrate. The coating has a lower Young's modulus than the semiconductor substrate.

In another example, an apparatus includes a semiconductor substrate, a BAW resonator, and protrusion structures. The BAW resonator is on a first side of the semiconductor substrate. The protrusion structures have uniform dimensions and are on a second side of the semiconductor substrate.

In a further example, an apparatus includes a semiconductor substrate, a BAW resonator, and a spur mitigation device. The semiconductor substrate has a thickness of no more than 100 micrometers. The BAW resonator is on a first side of the semiconductor substrate. The spur mitigation device is on a second side of the semiconductor substrate.

### BRIEF DESCRIPTION OF THE DRAWINGS

FIG. 1 is a graph of resonant frequency versus temperature in an example bulk acoustic wave (BAW) resonator exhibiting an abrupt frequency change caused by high-overtone bulk acoustic resonance (HBAR).

FIG. 2 is a cross sectional view of an example BAW resonator that includes a backside spur mitigation device to reduce HBAR and improve frequency stability over temperature.

FIG. 3 is a cross sectional view of an example BAW resonator that includes a backside coating to absorb HBAR.

FIG. 4 is a graph of example loss factors of spurious mode versus frequency in BAW resonators with backside coating materials having various stiffness values.

FIG. 5 is a graph of example loss factors of spurious mode versus coating thickness in BAW resonators with a variety of backside coating materials.

FIG. 6 is a cross sectional view of an example BAW resonator that includes a backside protrusion structure with normal sidewalls to reduce HBAR and improve frequency stability over temperature.

FIG. 7 is a depiction of acoustic reflection with destructive interference in an example BAW resonator with a protrusion structure having normal sidewalls.

FIG. 8 is a graph of reflection coefficient versus frequency in an example BAW resonator with a protrusion structure having normal sidewalls.

FIG. 9 is a cross sectional view of an example BAW resonator that includes a trapezoidal protrusion structure with angled sidewalls to reduce HBAR and improve frequency stability over temperature.

FIG. 10 is a graph of example reflection coefficients versus frequency in a BAW resonator having a protrusion structure with various sidewall angles.

FIG. 11 is a graph of example reflection coefficients versus frequency in a BAW resonator having a protrusion structure with various linewidth and pitch values.

FIG. 12 is a graph of example reflection coefficients versus frequency in a BAW resonator having a protrusion structure with various depth values.

FIG. 13 is a cross sectional view of an example BAW resonator that includes a triangular protrusion structure with angled sidewalls to reduce HBAR and improve frequency stability over temperature.

FIG. 14 is a depiction of lateral acoustic reflection in an example BAW resonator with a protrusion structure having angled sidewalls.

FIG. 15 is a cross sectional view of an example BAW resonator that includes a protrusion structure having angled and normal sidewalls to reduce HBAR and improve frequency stability over temperature.

FIG. 16 is a cross sectional view of an example BAW resonator that includes a protrusion structure and a conformal backside coating to reduce HBAR and improve frequency stability over temperature.

FIG. 17 is a flow diagram for an example method of forming a BAW resonator having a backside spur mitigation device.

FIG. 18 is a block diagram of an example oscillator that includes the BAW resonator with a backside spur mitigation device as described herein.

### DETAILED DESCRIPTION

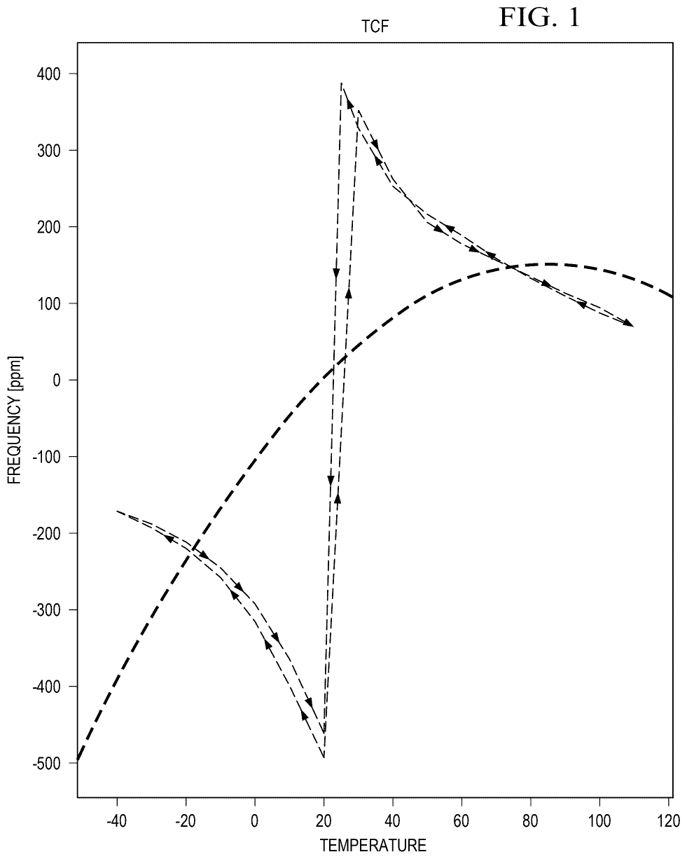

FIG. 1 is graph of frequency versus temperature in an example bulk acoustic wave (BAW) resonator. As shown in FIG. 1, BAW resonators are subject to a large kink or an abrupt shift in the frequency vs. temperature behavior, such as a temperature coefficient of frequency (TCF) kink, which can occur suddenly at a temperature around a typical BAW resonator operating temperature (e.g., around 15° Celsius (C)), and can lead to a resonant frequency increase of up to 1000 ppm over a narrow temperature range of several ° C. This sudden and undesirable TCF kink effect can occur at arbitrary temperatures, making it difficult to predict or control. The TCF kink is caused by mode-hopping due to coupling of the main cavity resonance of the BAW resonator with a second mode resulting from reflection of acoustic waves from the backside of substrate, resulting in high-overtone bulk acoustic resonance (HBAR) modes that cause the TCF kink.

One way to reduce the HBAR modes is by creating a roughened bottom surface of a substrate on which the BAW resonator is mounted. The roughened bottom surface can include a random rough pattern with non-uniform thickness (e.g., about 2 micro-meter (μm) root-mean-squared (RMS) surface roughness) to scatter acoustic signals after they are reflected off the bottom surface. Such arrangements can be effective for thicker substrates (e.g., 200 μm substrates), but may be ineffective with thinner substrates (e.g., 100 μm, 150 μm, or 200 μm substrates). This can be because with reduced substrate thickness, substantial amount of acoustic signals can still be reflected towards the BAW resonator by the roughened bottom surface. Therefore, substantial HBAR modes may remain, which causes the TCF kink. A thin substrate can be advantageous as it can reduce the amount of material used in creating the wafer, which reduces cost. The overall package size of an integrated circuit including the thin substrate can also be reduced.

In some examples, a BAW resonator includes a backside spur mitigation device that can effectively reduce the HBAR modes even for thin substrates (e.g., 200 μm, 150 μm, 100 μm or below). Some examples of the backside spur mitigation device can include a coating on the backside of the substrate that absorbs acoustic waves. Some examples of the backside spur mitigation device can include a protrusion structure provided on the backside of the substrate. The protrusion structure has uniform dimensions to reflect acoustic waves away from the BAW resonator, or reflect the acoustic waves with phase shift to produce destructive interference.

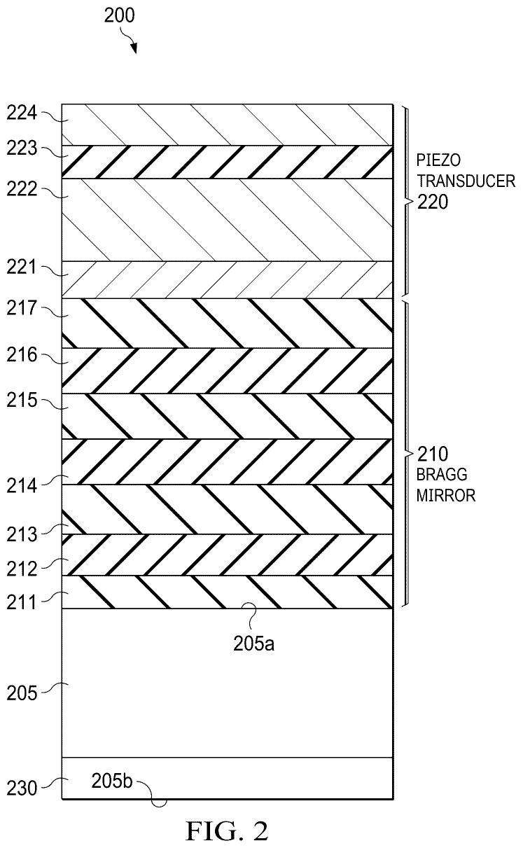

FIG. 2 is a cross sectional depiction of an example BAW resonator 200 that includes a backside spur mitigation device 230 to reduce HBAR and improve frequency stability over temperature. The BAW resonator 200 may include a substrate 205, a piezoelectric transducer 220, a Bragg mirror 210, and the backside spur mitigation device 230. The substrate 205 has a top side surface (or top surface) 205a and a bottom side surface (or bottom surface) 205b. The Bragg mirror 210 is on the top side surface 205a of the substrate. Bragg mirror 210 may include a plurality of layers with alternating high and low acoustic impedance layers, with the relatively high acoustic impedance layers shown as layers 212, 214, and 216, alternating with the relatively low acoustic impedance layers 211, 213, 215, and 217. In the example shown in FIG. 2, Bragg mirror 210 includes three pair of alternating high and low acoustic impedance layers. In other examples, Bragg mirror 210 may include a different number of pairs of alternating high and low acoustic impedance layers. The thickness of each of the layers 211-217 can be at about one quarter wavelength of the desired resonant frequency (or one quarter of the resonant wavelength). The piezoelectric transducer 220 includes a bottom electrode layer 221 that is on layer 217 of the Bragg mirror 210, a piezoelectric layer 222 on the bottom electrode layer 221, a dielectric layer 223 on the piezoelectric layer 222, and a top electrode layer 224 on the dielectric layer 223. Some examples of the BAW resonator 200 may include a second Bragg mirror 210 provided on the top electrode layer 224 of the piezoelectric transducer 220.

The backside spur mitigation device 230 is on the bottom side surface 205b of the substrate 205. In some examples, the backside spur mitigation device 230 can include a coating that absorbs acoustic energy and/or a protrusion structure that reflects acoustic energy. In some examples, the protrusion structure may reflect acoustic energy laterally away from the piezoelectric transducer 220. In some examples, the protrusion structure may reflect acoustic energy with a phase selected to produce destructive interference of the HBAR waves.

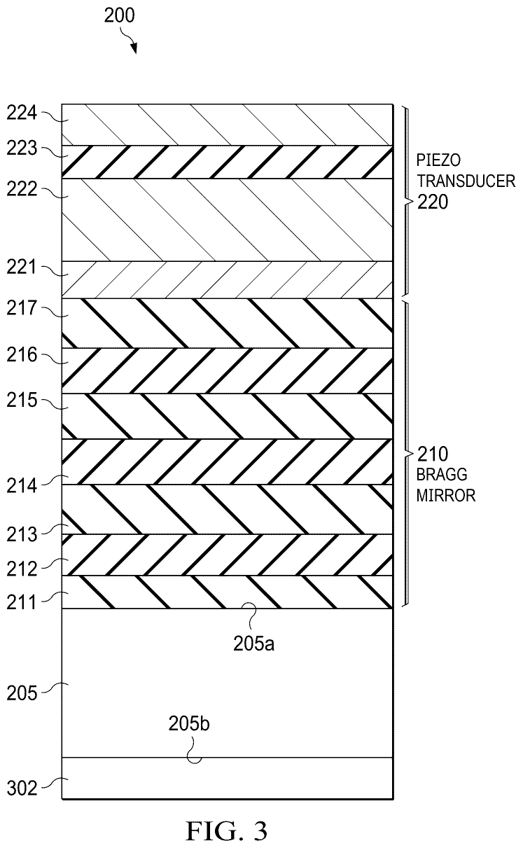

FIG. 3 is a cross sectional depiction of an example BAW resonator 200 that includes a backside coating 302 to absorb acoustic signals that propagate from the BAW resonator towards the bottom surface of the substrate, which can reduce the amount of acoustic signals reflected from the bottom surface towards the BAW resonator and reduce HBAR. In some examples, the effectiveness of the backside coating 302 may be a function of the acoustic impedance of the backside coating 302 and/or the stiffness of the backside coating 302. For example, use of a backside coating 302 having an acoustic impedance relatively close to the acoustic impedance of the of the substrate 205 (e.g., silicon) facilitates propagation of acoustic energy into to the backside coating 302 for absorption. Table 1 shows values of Young's modulus (E) with units of giga-Pascals (Gpa), acoustic impedance (Z11) with units of mega-Rayls (MR), and propagation velocity (V11) with units of meters per second (m/s). Silicon is included in Table 1, with a Young's modulus of 100 and an acoustic impedance of 21.3.

TABLE 1

| E (Gpa) | Z11 (MR) | V11 (m/s) |
|---|---|---|
| 0.1 | 0.537 | 298.6 |
| 0.5 | 1.202 | 667.7 |
| 1.0 | 1.700 | 944.3 |
| 5.0 | 3.801 | 2111.4 |
| 10.0 | 5.375 | 2986.0 |
| 25.0 | 8.498 | 4721.3 |
| SI 100 | 21.3 | 9130.7 |

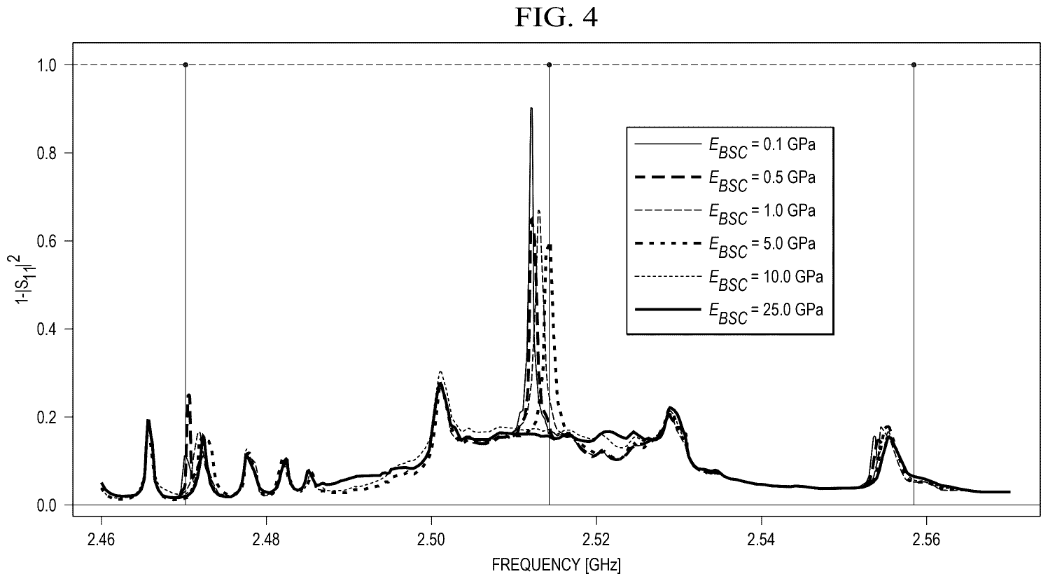

FIG. 4 is a graph of example of loss factors (1−|S11|²) versus frequency in BAW resonators with a backside coating material having the stiffness values shown in Table 1. The peaks in the loss factors can represent HBAR. The frequency range shown is selected based on the main resonance of a BAW resonator. In FIG. 4, the materials with Young's moduli of 10 Gpa and above have an acoustic impedance (Z11) closest to that of silicon and provide the best absorption of acoustic energy, where there are no (or reduced) peaks. With Young's moduli below 10 Gpa, the absorption of acoustic energy by the coating can be less effective, and huge peaks (and substantial HBAR) may result due to substantial reflection from the coating.

Materials used in the backside coating 302 can include porous materials or materials that have a filler for absorbing acoustic energy, where the materials have an acoustic impedance that is similar to that of the substrate 205. Such materials may include a hardened resin, such as integrated circuit mold compound.

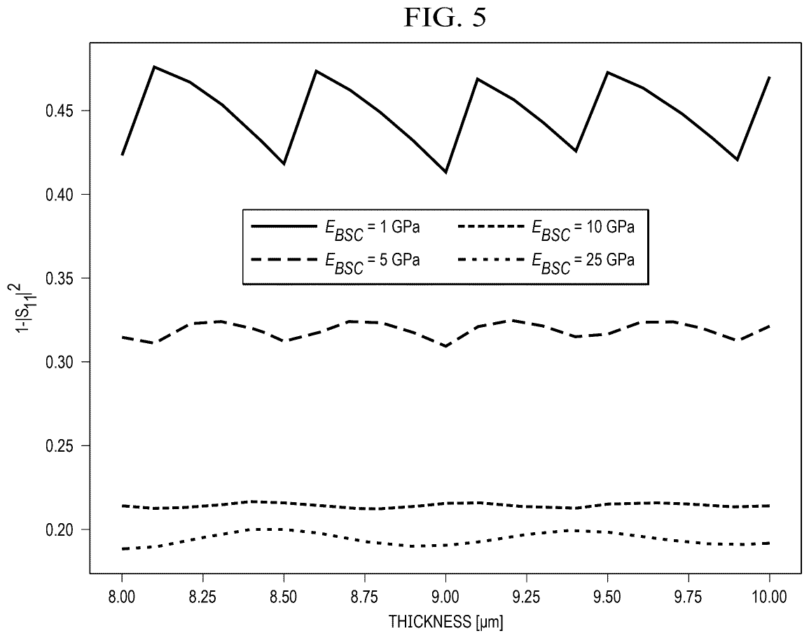

Softer coating materials (e.g., polymers) that have a large acoustic impedance mismatch with the substrate 205 may also be used if the thickness of the material is controlled. For example, the thickness of the coating can be controlled such that the material forms a quarter wavelength transformer that passes acoustic energy in a selected range. FIG. 5 is a graph of example the loss factors (1−|S11|²)) versus coating thickness in BAW resonators in BAW resonators with a backside coating material having Young's moduli of 1, 5, 10, and 25 GPa. For the stiffer materials (Young's moduli of 5, 10, and 25 GPa) variation of reflection coefficient with thickness is relatively small. However, for the more elastic material (Young's modulus of 1 GPa), the reflection coefficient changes substantially with thickness. Parylene is an example of a soft material that may be used in the backside coating 302 if the thickness can be adequately controlled.

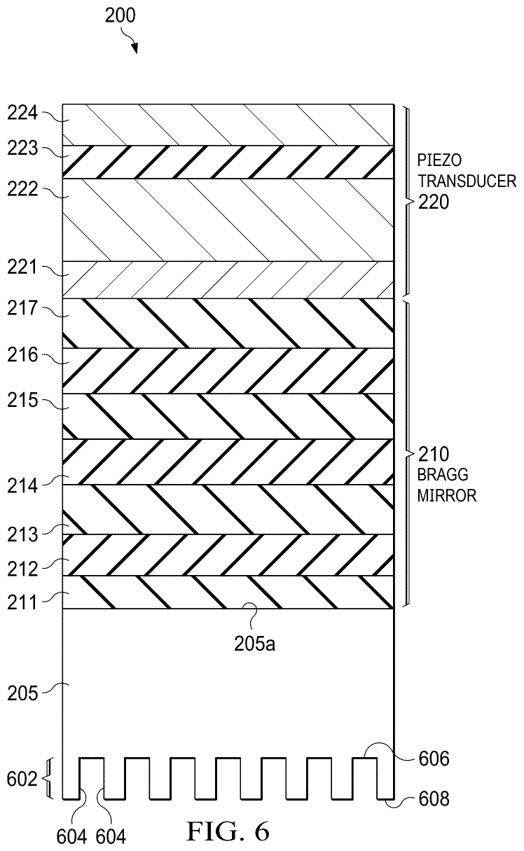

FIG. 6 is a cross sectional depiction of the BAW resonator 200 that includes a backside protrusion structure 602 to reduce HBAR and improve frequency stability over temperature. The backside protrusion structure 602 includes rectangular projections having sidewalls 604 that are normal to the top surface 606 and the bottom surface 608 of the projections. The backside protrusion structure 602 includes a uniform/periodic structure, in which at least some of the protrusion structures have a uniform height and/or uniform spacing between the protrusion structures. The backside protrusion structure 602 receives acoustic energy through the substrate 205, and reflects acoustic waves in a selected frequency range with phase shifts, set by the uniform height of the protrusion structures and/or the uniform spacing between the protrusion structures, to induce destructive interference of the reflected acoustic waves in the substrate and thereby mitigate HBAR.

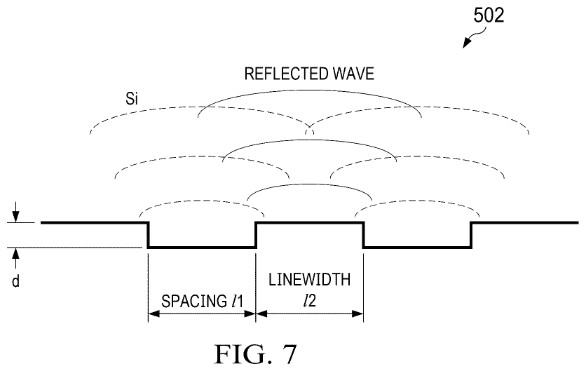

FIG. 7 is a depiction of acoustic reflection in the backside protrusion structure 602, according to some examples. The backside protrusion structure 602 have height/depth (sidewall length) d, spacing (bottom surface length) l1, and width/linewidth (top surface width) l2. The depth d can be selected so that waves reflected from the top surface 606 and the bottom surface 608 have a phase difference of about π at a selected frequency, which causes the waves to destructively interfere with each other. To minimize the overall resonance, the depth d can be selected as:

$$d = \frac{( 2 n + 1 ) λ}{4} \qquad ( 1 )$$

where n can be 0 or 1.

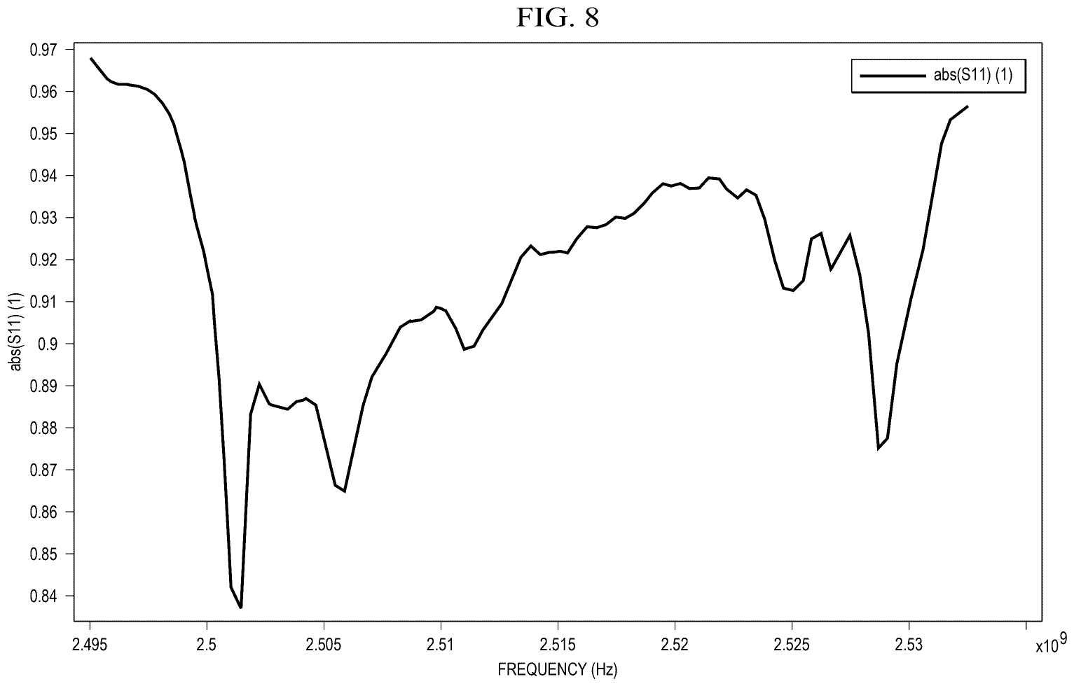

FIG. 8 is a graph of reflection coefficients (S11) versus frequency in the BAW resonator 200 with the backside protrusion structure 602, where d=λ/4. A relatively high S11 (between 0.84-0.96) over a frequency range can indicate that HBAR is attenuated/eliminated.

To provide good spur mitigation in a frequency range of (fmin, fmax), d may be selected as:

$$\frac{1}{8} {λ}_{max} < d < \frac{3}{8} {λ}_{min} for n = 0 , or \qquad ( 2 )$$

$$\frac{5}{8} {λ}_{max} < d < \frac{7}{8} {λ}_{min} for n = 1 , \qquad ( 3 )$$

where (λₘᵢₙ, λₘₐₓ) are the acoustic wavelengths corresponding to (fmin, fmax).

In some examples, the sidewalls 604 may be angled from the bottom surface. With angled sidewalls 604, d may be larger

$$( e . g . , d = \frac{3}{4} λ )$$

because the angled sidewall can further tune the reflection direction and enhance interference. In the backside protrusion structure 602, to provide good diffraction and interference between two reflected waves, the linewidth (l2) and spacing (l1) can be selected as:

$$l 1 , l 2 < 5 λ , l 1 : l 2 ∼ 1 : 1.5 to 1.5 : 1 \qquad ( 4 )$$

With a piezoelectric transducer 220 of a lateral length l_{BAW}, the linewidth and spacing of the backside protrusion structure 602 can be selected as:

$$l 1 , l 2 < {l}_{BAW} / 2 \qquad ( 5 )$$

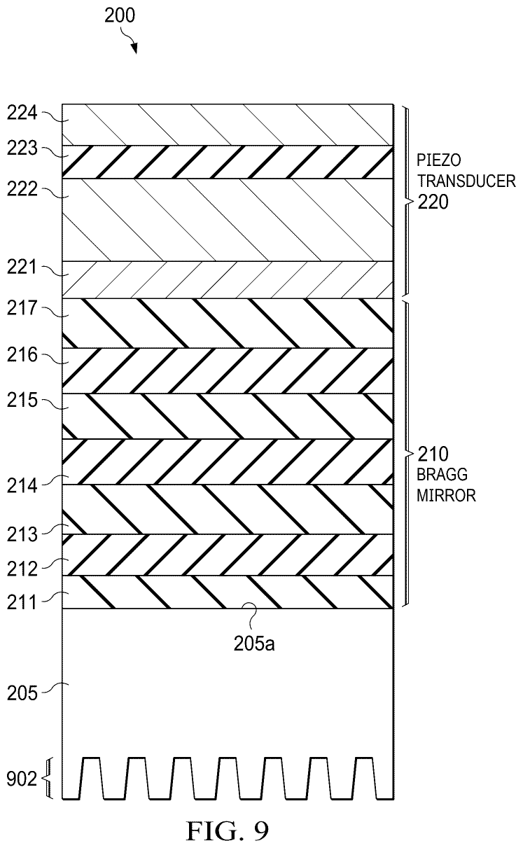

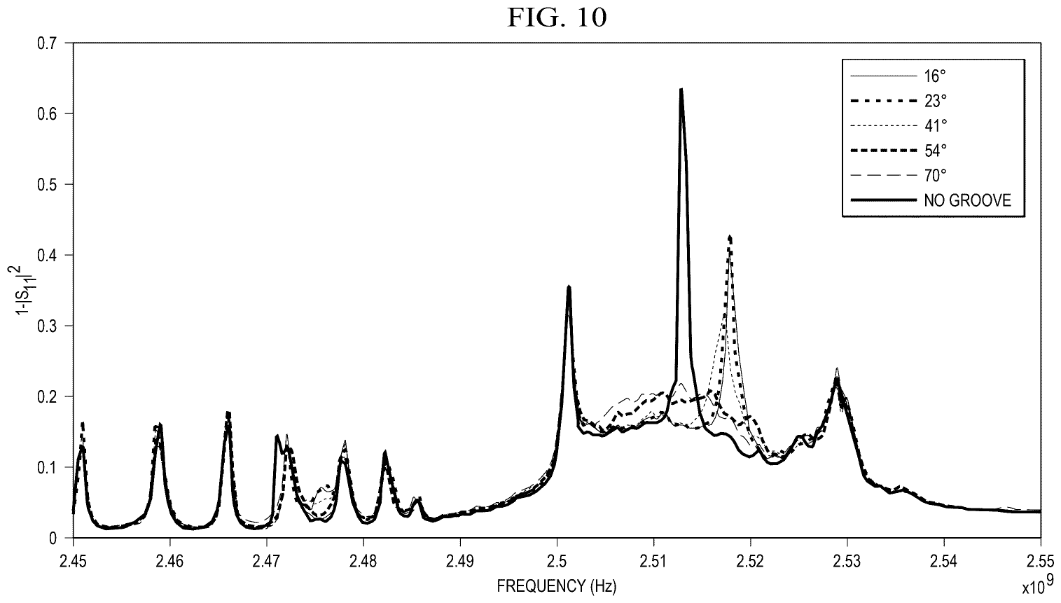

FIG. 9 is a cross sectional depiction of an example BAW resonator that includes a backside protrusion structure 902 with angled sidewalls. The protrusions of the backside protrusion structure 902 are trapezoidal FIG. 10 is a graph of example reflection coefficient (S11) versus frequency in the BAW resonator of FIG. 9 with various sidewall angles. In the backside protrusion structure 902 used in FIG. 10, d=2 μm, l2=12 μm, and pitch=20 μm. The example angles of the sidewalls are 16°, 23°, 41°, 54°, and 70°. Smooth backside data is also provided for reference. FIG. 10 shows that larger sidewall angles can provide a larger ratio of angled surface and better spur mitigation.

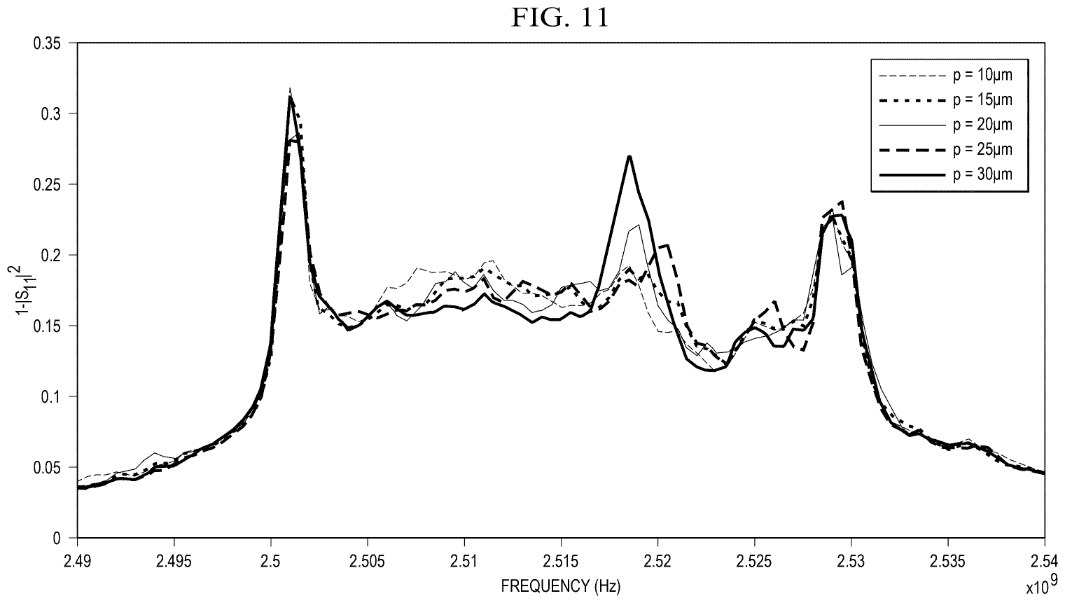

FIG. 11 is a graph of example reflection coefficients (S11) versus frequency in the BAW resonator of FIG. 9 with various linewidth and pitch values. In FIG. 10, the backside protrusion structure 902 has a 54° sidewall angle and d=2 μm. Pitch values of 10, 15, 20, 25, and 30 μm with l2 of 8, 12, 16, 20, and 24 respectively are shown. FIG. 11 shows that smaller pitch can provide a larger ratio of angled surface and better spur mitigation.

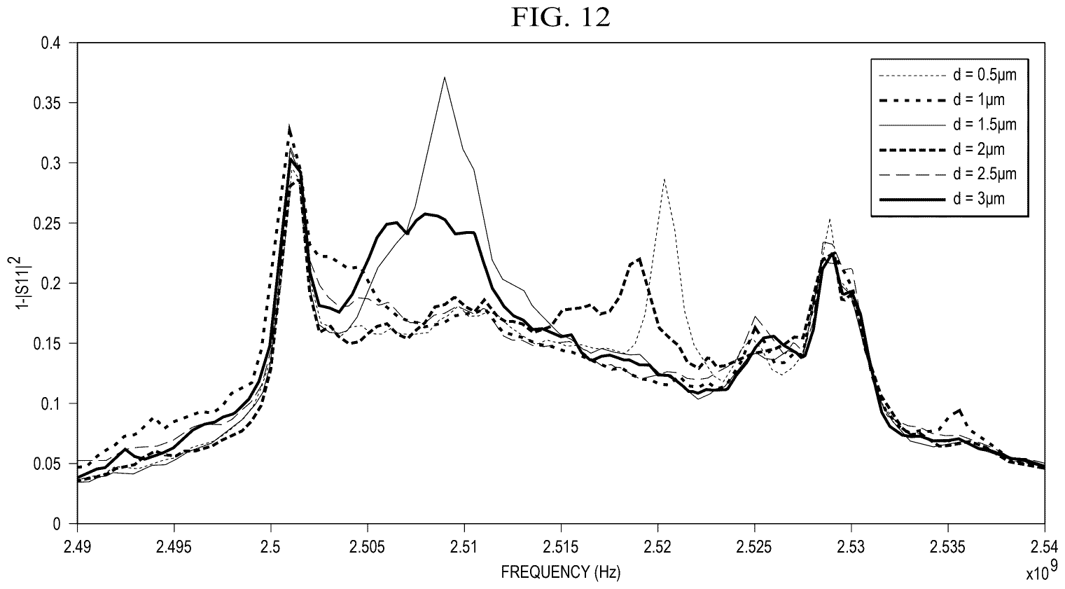

FIG. 12 is a graph of example reflection coefficient (S11) versus frequency in the BAW resonator of FIG. 9 with various depth values. In FIG. 10, the backside protrusion structure 902 has a 54° sidewall angle, 20 μm pitch, and l2=16 μm. Depths of 0.5, 1, 1.5, 2, 2.5, and 3 μm are shown. FIG. 12 shows that depths of about 2-2.8 μm (near 3λ/4) provide phase difference near π, and better spur mitigation.

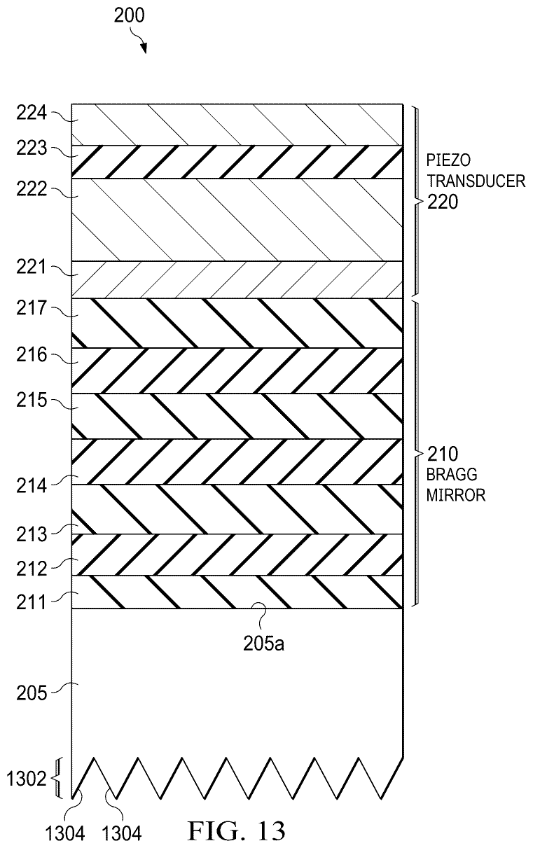

FIG. 13 is a cross sectional depiction of an example BAW resonator that includes a backside protrusion structure 1302 to reduce HBAR and improve frequency stability over temperature. The backside protrusion structure 1302 includes triangular projections with angled sidewalls 1304. The angled sidewalls 1304 may reflect acoustic energy laterally away from the piezoelectric transducer 220, and the reflected acoustic waves may destructively interfere with each other.

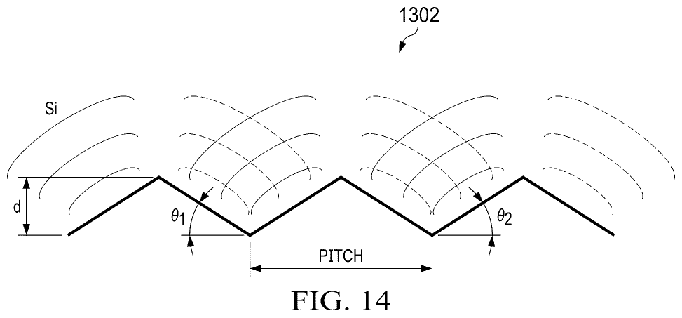

FIG. 14 is a depiction of the backside protrusion structure 1302 and lateral acoustic reflection provided the backside protrusion structure 1302. The sidewall angles θ₁ and θ₂ may be selected as θ₁, θ₂>10°, with a depth of

$$d > \frac{λ}{4} .$$

Various values of pitch may be used.

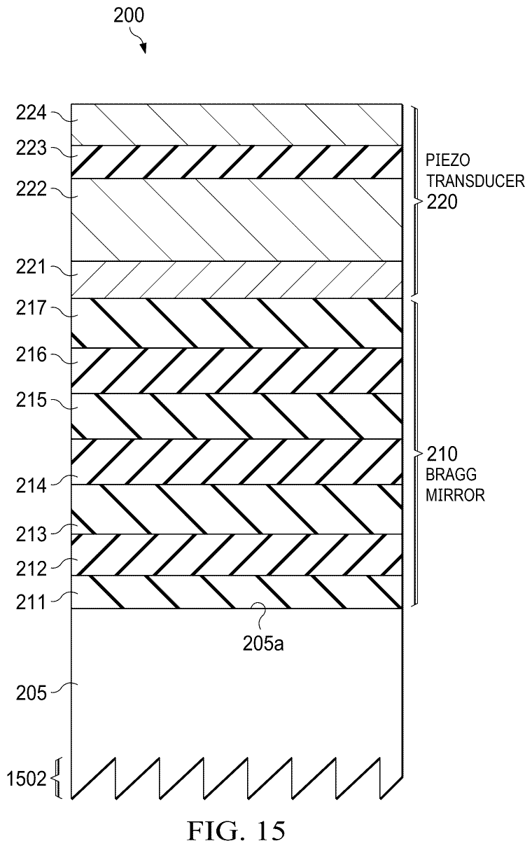

FIG. 15 is a cross sectional depiction of an example BAW resonator that includes a backside protrusion structure 1502 to reduce HBAR and improve frequency stability over temperature. The backside protrusion structure 1502 includes ramp-shaped protrusions. In some examples the backside protrusion structure 1502 can include ramps arranged as annular concentric rings (as in a Fresnel lens), where the ramp-shaped protrusions reflect acoustic energy away from the piezoelectric transducer 220.

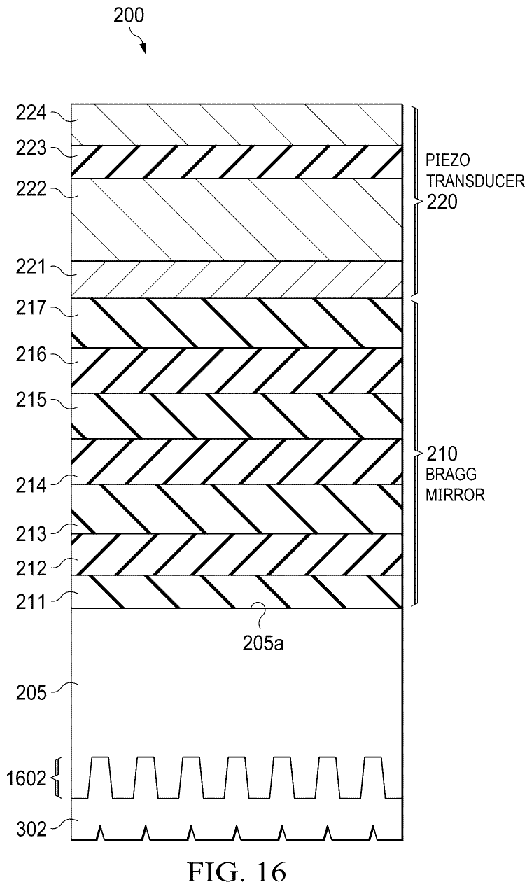

FIG. 16 is a cross sectional depiction of an example BAW resonator that includes a backside protrusion structure 1602 and a backside coating 302 to reduce HBAR and improve frequency stability over temperature. The backside protrusion structure 1602 can be an example of the backside protrusion structure 602, the backside protrusion structure 902, the backside protrusion structure 1302, or the backside protrusion structure 1502. The backside coating 302 can be conformal to the backside protrusion structure 1602. The backside protrusion structure 1602 and backside coating 302 work together to reduce HBAR modes by reflecting and absorbing acoustic energy received through the substrate 205.

Some examples of a backside protrusion structures described herein (e.g., protrusion structures 602, backside protrusion structure 902, backside protrusion structure 1302, and backside protrusion structure 1502) can have uniform dimensions, such that the various parameters of the backside protrusion structure (d, l1, l2, pitch, and sidewall angle) are uniform throughout the backside protrusion structure. In some examples of the backside protrusion structure described herein, a first set of the backside protrusion structure can have first uniform dimensions, and set portion of the backside protrusion structure can have second uniform dimensions that are different from the first uniform dimensions. Some examples of the backside protrusion structure can have more than 2 sets of protrusion structures, each with uniform dimensions that are different from the uniform dimensions of other portions of the backside protrusion structure.

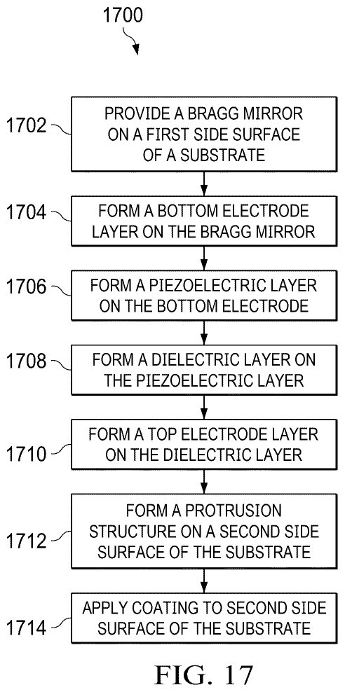

FIG. 17 is a flow diagram for an example method 1700 of forming a BAW resonator having a backside spur mitigation device. Though depicted sequentially as a matter of convenience, at least some of the actions shown can be performed in a different order and/or performed in parallel. Additionally, some implementations may perform only some of the actions shown.

In block 1702, a Bragg mirror 210 is provided on a top side surface 205a of a substrate 205 having a bottom side surface 205b opposite the top side surface 205a. The substrate 205 can include a variety of different materials including silicon, silicon carbide (SiC), sapphire (Al₂O₃) or glass. The silicon can be n-type or p-type, in a wide range of doping levels.

Blocks 1704-1710 describe forming a piezoelectric transducer 220. In block 1704, a bottom electrode layer 221 is formed on the Bragg mirror 210. One example metal for the bottom electrode layer 221 is Mo. Other example possibilities for the bottom electrode layer 221 include Pt, W, and Ir.

In block 1706, a piezoelectric layer 222 is formed on the bottom electrode layer 221. One example piezoelectric layer material is AlN. Other example possibilities for the piezoelectric layer 222 include ZnO and Lead Zirconate Titanate (PZT).

In block 1708, a top dielectric layer 223 is formed on the piezoelectric layer 222. The top dielectric layer 223 includes a material having a positive room temperature elastic modulus, such as silicon oxide. The top dielectric layer 223 can comprise other materials, such as silicon oxynitride or silicon nitride.

In block 1710, a top electrode layer 224 is formed on the top dielectric layer 223 to complete the piezoelectric transducer 220. One example metal for the top electrode layer 224 is Mo. Other example possibilities for the top electrode layer 224 include Pt, W, and Ir.

In block 1712, a backside protrusion structure is formed on the bottom side surface 205b of the substrate 205. The backside protrusion structure may be an example of the backside protrusion structure 602, the backside protrusion structure 902, the backside protrusion structure 1302, or the backside protrusion structure 1502. A variety of fabrication methods may be employed to form the backside protrusion structure. Laser ablation can be applied to the bottom side surface 205b to form the backside protrusion structure in some examples. Wet or dry etching can be used to form the backside protrusion structure in some examples.

In block 1714, a backside coating 302 is applied to the bottom side surface 205b of the substrate 205. The backside coating 302 may be applied to the bottom side surface 205b of the substrate 205. The backside coating 302 can be applied over the backside protrusion structure or to the bottom side surface 205b without the backside protrusion structure. The backside coating 302 may be applied using, for example, spin coating, physical vapor deposition, spray coating, dry film laminating, or other suitable methods.

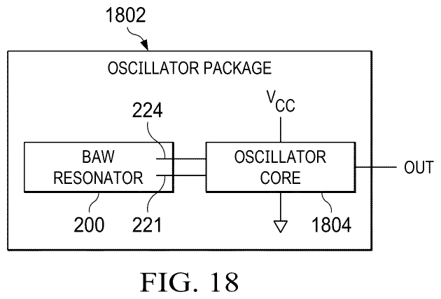

FIG. 18 is a block diagram of an example oscillator package 1802 that includes an oscillator core 1804 and the BAW resonator 200 having a backside spur mitigation device 230. The oscillator package 1802 can be a stacked package (e.g., flip chip assembly) or a lateral package arrangement. It may also be possible for the BAW resonator 200 and oscillator core 1804 to be formed on the same die. The oscillator core 1804 has bond pads (not shown) for being coupled between a high voltage supply terminal shown as VCC and a low voltage shown as a ground, and to the electrodes 224 and 221 of the piezoelectric transducer 220 of the AW resonator 200. The piezoelectric transducer 220 of the BAW resonator 200 functions as a reference signal generator which provides the signal input for the oscillator core 306.

Oscillator core 306 includes active and passive circuit elements (e.g., capacitors) capable of sustaining oscillations and amplifying the signal from the piezoelectric transducer 220 of the BAW resonator 200 to provide the output signal shown as shown as OUT. The construction of the BAW resonator 200 (the thickness of the piezoelectric layer 222) selects the oscillation frequency. Regarding oscillator core, it can in one particular example comprise a Colpitts oscillator.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. An apparatus comprising:
a semiconductor substrate;
a bulk acoustic wave (BAW) resonator on a first side of the semiconductor substrate; and
a coating on a second side of the semiconductor substrate, the coating having a lower Young's modulus than the semiconductor substrate.

2. The apparatus of claim 1, wherein the coating includes at least one of a polymer or a resin.

3. The apparatus of claim 1, wherein the coating has a Young's modulus of at least 10 giga-Pascals.

4. The apparatus of claim 1, wherein the coating has an acoustic impedance of at least 5.3 mega-Rayls.

5. The apparatus of claim 1, wherein the coating has a thickness of about one quarter of a resonant wavelength of the BAW resonator.

6. The apparatus of claim 1 further comprising protrusion structures having uniform dimensions on the second side of the semiconductor substrate between the coating and the BAW resonator.

7. The apparatus of claim 6, wherein the protrusion structures include protrusions having a depth (d) based on a frequency range of reflected acoustic signals to be suppressed.

8. The apparatus of claim 6, wherein a width of each protrusion structure, and a spacing between adjacent protrusion structures is less than about 5λ, where λ is a resonant wavelength of the BAW resonator, and a ratio of the spacing to the width is in a range of about 1:1.5 to 1.5:1.

9. The apparatus of claim 6, wherein a width of each protrusion structure, and a spacing between adjacent protrusion structures is less than about half a lateral length of the BAW resonator.

10. The apparatus of claim 6, wherein a sidewall angle of the protrusion structures is greater than 10° and depth of the protrusion structures is greater than one quarter of a resonant wavelength of the BAW resonator.

11. The apparatus of claim 6, wherein the protrusion structures include:
a first set of protrusion structures having first uniform dimensions; and
a second set of protrusion structures having second uniform dimensions; and
the first uniform dimensions are different from the second uniform dimensions.

12. An apparatus comprising:
a semiconductor substrate;
a bulk acoustic wave (BAW) resonator on a first side of the semiconductor substrate; and
protrusion structures having uniform dimensions on a second side of the semiconductor substrate.

13. The apparatus of claim 12, wherein the protrusion structures include:
a first set of protrusion structures having first uniform dimensions; and
a second set of protrusion structures having second uniform dimensions; and
the first uniform dimensions are different from the second uniform dimensions.

14. The apparatus of claim 12, wherein a sidewall angle of the protrusion structures is greater than 10° and depth of the protrusion structures is greater than one quarter of a resonant wavelength of the BAW resonator.

15. The apparatus of claim 12, wherein a width of each protrusion structure, and a spacing between adjacent protrusion structures is less than about half a width of the BAW resonator.

16. The apparatus of claim 12, wherein a width of each protrusion structure, and a spacing between adjacent protrusion structures is less than about 5λ, where λ is a resonant wavelength of the BAW resonator, and a ratio of the spacing to the width is in a range of about 1:1.5 to 1.5:1.

17. The apparatus of claim 12, wherein the protrusion structures include protrusions having a depth (d) based on a frequency range of reflected acoustic signals to be suppressed.

18. The apparatus of claim 12, further comprising a coating on a second side of the semiconductor substrate, the coating having a lower Young's modulus than the semiconductor substrate.

19. The apparatus of claim 18, wherein the coating has a Young's modulus of at least 10 giga-Pascals.

20. The apparatus of claim 18, wherein the coating has an acoustic impedance of at least 5.3 mega-Rayls.

21. The apparatus of claim 18, wherein the coating has a thickness of about one quarter of a resonant wavelength of the BAW resonator.

22. An apparatus comprising:
a semiconductor substrate having a thickness of no more than 100 micro-meters;
a bulk acoustic wave (BAW) resonator on a first side of the semiconductor substrate; and
a spur mitigation device on a second side of the semiconductor substrate.

23. The apparatus of claim 22, wherein the spur mitigation device includes a coating configured to absorb acoustic energy received from the semiconductor substrate.

24. The apparatus of claim 22, wherein the spur mitigation device includes a protrusion structure having uniform dimensions configured to reflect acoustic energy received from the semiconductor substrate with a phase shift that produces destructive interference in a selected frequency range.

25. The apparatus of claim 22, wherein the spur mitigation device includes a protrusion structure having protrusions with a sidewall angle selected to reflect acoustic energy received from the semiconductor substrate away from the BAW resonator.
